(19) United States
(12) Patent Application Publication
(10) Pub. No.: US 2014/0077234 A1
(43) Pub. Date: Mar. 20, 2014

(54) SEMICONDUCTOR STRUCTURE WITH PATTERNED BURIED LAYER

(71) Applicant: Joseph M. Freund, Fogelsville, PA (US)

(72) Inventor: Joseph M. Freund, Fogelsville, PA (US)

(73) Assignee: LSI Corporation, Milpitas, CA (US)

(21) Appl. No.: 13/617,169

(22) Filed: Sep. 14, 2012

(51) Int. Cl. H01L 33/20; H01L 27/15; H01L 33/32

(52) U.S. Cl. 257/88; 257/95; 438/39; 257/E33.005; 257/E33.032; 257/E27.12

(57) ABSTRACT

An apparatus comprises a substrate, a first buried layer formed over the substrate, the first buried layer comprising one or more raised mesa structures, a second buried layer formed over the first buried layer, an active layer formed over the second buried layer, and a capping layer formed over the active layer. The apparatus may further comprise a third buried layer formed over the active layer, the third buried layer comprising one or more raised mesa structures, and a fourth buried layer formed over the third buried layer. The one or more raised mesa structures of the first buried layer may be offset from the one or more raised mesa structures of the third buried layer.

### BACKGROUND

Solid-state lighting (SSL) technologies are used in a wide variety of lighting applications. As SSL technologies improve in areas such as energy efficiency, cost, and lifespan, such technologies represent viable alternatives to conventional lighting technologies in general illumination and display applications. One example of an SSL technology is semiconductor light-emitting diodes (LEDs). Semiconductor LEDs are used in various electronic, display and lighting applications. For example, display screens on devices such as televisions, monitors, and cell phones may use LED-backlit displays.

Nitride-based LEDs are one example LED type. Nitride LED improvements have focused on increasing light extraction rather than improving light generation efficiency. Flip-chip configurations of nitride LEDs have become widely used. In flip-chip configurations, light is emitted through the substrate on which the LED structures are grown. Light generation in flip-chip configurations, however, is not limited to a specific direction. Therefore, in order to increase light output, techniques for reflecting light emitted from the substrate in a desired direction are typically used.

### SUMMARY

An illustrative embodiment of the present invention provides enhanced light extraction efficiency in an LED structure.

In one embodiment of the invention, an apparatus comprises a substrate, a first buried layer formed over the substrate, the first buried layer comprising one or more raised mesa structures, a second buried layer formed over the first buried layer, an active layer formed over the second buried layer, and a capping layer formed over the active layer.

More particularly, in one or more embodiments the second buried layer may be formed such that one or more hollows of the one or more raised mesa structures of the first buried layer are filled.

At least one of the first buried layer and the second buried layer may comprise a distributed Bragg reflector (DBR).

The apparatus may further comprise a third buried layer formed over the active layer, the third buried layer comprising one or more raised mesa structures, and a fourth buried layer formed over the third buried layer.

The first buried layer and the second buried layer may be doped with a first conductivity type and the third buried layer and the fourth buried layer may be doped with a second conductivity type different than the first conductivity type.

The one or more raised mesa structures of the first buried layer may be offset from the one or more raised mesa structures of the third buried structure layer.

### BRIEF DESCRIPTION OF THE DRAWINGS

FIG. 1 shows a LED display device, according to an illustrative embodiment of the invention.

FIGS. 2-9 show cross-sectional views depicting steps in forming an exemplary LED structure, according to an embodiment of the invention.

FIG. 10 shows a cross-sectional view of an alternate LED structure, according to an embodiment of the invention.

FIG. 11 shows a cross-sectional view of another alternate LED structure, according to an embodiment of the invention.

### DETAILED DESCRIPTION

Embodiments of the invention will be illustrated herein in conjunction with an exemplary apparatus, method, device, etc. It is to be understood, however, that techniques of the present invention are not limited to the apparatus, methods, and devices shown and described herein. Rather, the invention is more generally applicable to various other apparatus, methods and devices.

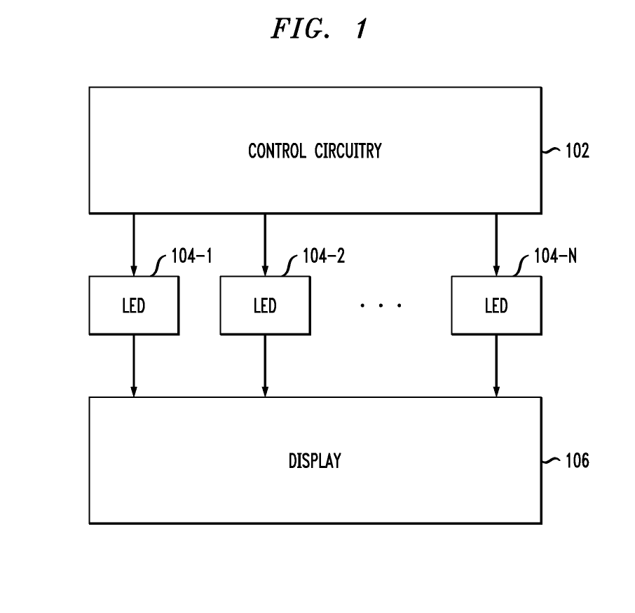

Embodiments of the invention provide an improved LED structure with higher output light extraction efficiency compared to conventional arrangements. The improved LED structure can be used in a wide variety of applications. For example, FIG. 1 illustrates an LED-backlit display. Control circuitry 102 is configured to control LEDs 104-1 to 104-N. As an example, control circuitry 102 may be operative to turn on and off one or more of the LEDs 104-1 to 104-N. The control circuitry may be further operative to adjust light output from the one or more LEDs 104-1 to 104-N. In other embodiments, the control circuitry may be operative to adjust or cut off the power supplied to the LEDs in a particular sequence. While not explicitly shown in FIG. 1, the control circuitry could also be coupled to various other components. By way of example, the control circuitry could be coupled to a processing device. The processing device may direct the control circuitry to turn on and off one or more of the LEDs such that the LEDs act as indicator lights. In another example, the control circuitry may be operative to control light output of the LEDs in accordance with optical signaling requirements for the transmission of data over fiber communication lines. One skilled in the art will readily appreciate that various other examples are possible and that embodiments of the invention are not limited to use solely in the above-described examples.

The LEDs 104-1 to 104-N are configured to illuminate display 106. Display 106 may be incorporated in a variety of devices, such as televisions, monitors, cell phones, tablets, etc. For example, the display 106 may be utilized as a backlight for such devices. In other embodiments, display 106 may represent a bulb which can be implemented in a streetlight, a car headlight, and various other personal, residential and commercial lighting applications. One skilled in the art will readily appreciate that the improved LED structure is not limited to use solely in the above-described examples, but may instead be implemented in a variety of other applications which incorporate LEDs.

To increase light extraction from LED structures, it is advantageous to reflect light emitted from the LED substrate in a useful direction. Incorporating distributed Bragg reflectors (DBRs) into LED structures is one technique for reflecting emitted light in a useful direction. DBRs facilitate constructive interference of light waves in LED structures to achieve desired reflections. DBRs utilize precise layers of alternating materials with different refractive indices to achieve desired interference effects. The relative thickness of the layers can be optimized using optical transfer matrix calculations. The relative dimensions may be adjusted based on the materials chosen for the DBR's alternating layers.

Reflection at the substrate-external interface for flip-chip LEDs, however, can prevent light from leaving the LED structure. Patterned substrates can increase light extraction efficiency by reducing reflection back into the LED at the substrate-external interface. The distance between patterned substrates and the active layers of LED structures can also affect light extraction efficiency. As the distance increases, the scattering probability decreases. Embodiments of the invention reduce the mean free path from the active region to patterned features of LED structures to increase the scattering probability. As the scattering probability increases, extraction efficiency also increases due to further reduction in reflection at the substrate-external interface of the LED structure.

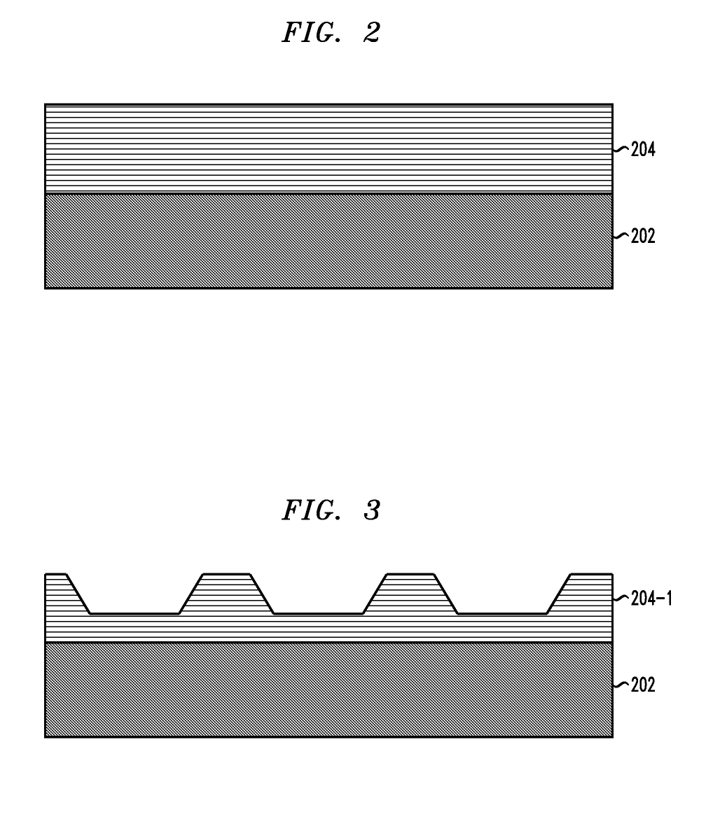

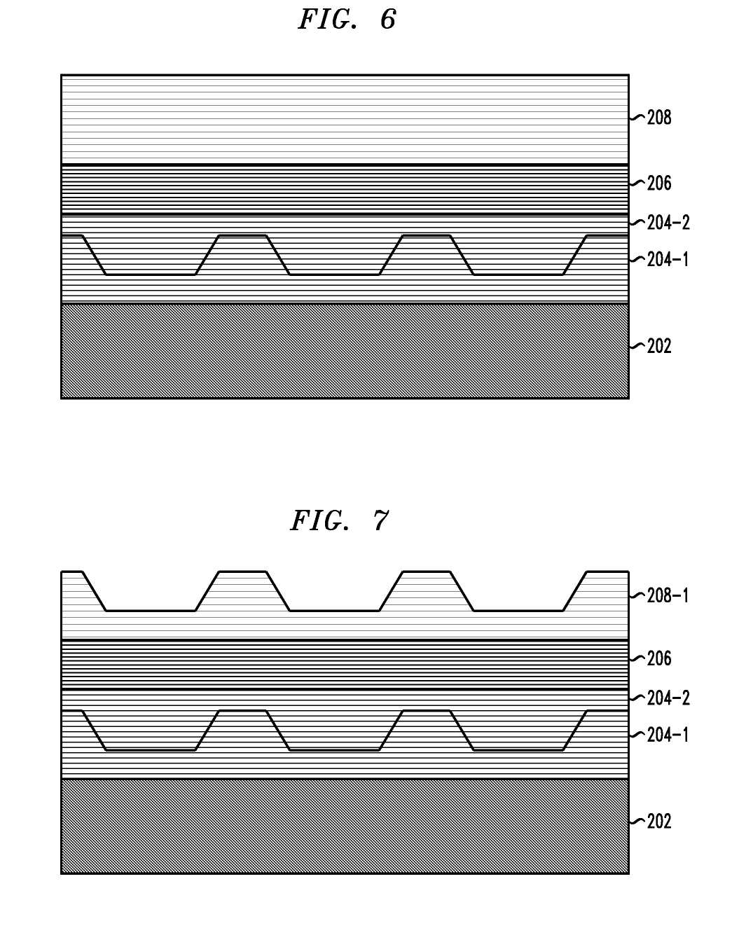

A method of forming an improved LED structure in accordance with an embodiment of the invention will now be described in conjunction with FIGS. 2-9. To begin, a substrate 202 is formed. Although substrate 202 as shown in FIG. 2 is not patterned, other embodiments of the invention may use patterned substrates as described below. The substrate 202 may be sapphire. Alternatively, the substrate 202 may comprise a sapphire substrate on which a Gallium Nitride (GaN) layer is grown. The substrate 202 may be grown using metal-organic chemical vapor deposition (MOCVD).

A buried layer 204 is formed over the substrate 202. The buried layer 204 may be a DBR formed by alternating layers of Indium Gallium Nitride (InGaN) and (GaN). In one embodiment, the substrate 202 is a 4.5 μm-thick layer of undoped GaN and the buried layer is a 3 μm-thick DBR formed of alternating layers of n-doped InGaN and GaN. It is important to note, however, that various other materials may be used. By way of example, the DBR may alternately be formed of layers of GaN and Aluminum Gallium Nitride (AlGaN). One skilled in the art will readily appreciate that other materials may be used, not only for the buried layers but for the substrate layer 202 and the active and capping layers described below.

The next step is to create patterned mesa structures in the buried layer 204. Inductively coupled-plasma reactive-ion etching (ICP-RIE) can be used to create the patterned mesas in the buried layer 204. FIG. 3 shows the resulting structure, with substrate 202 and the patterned buried layer 204-1 with patterned mesa structures.

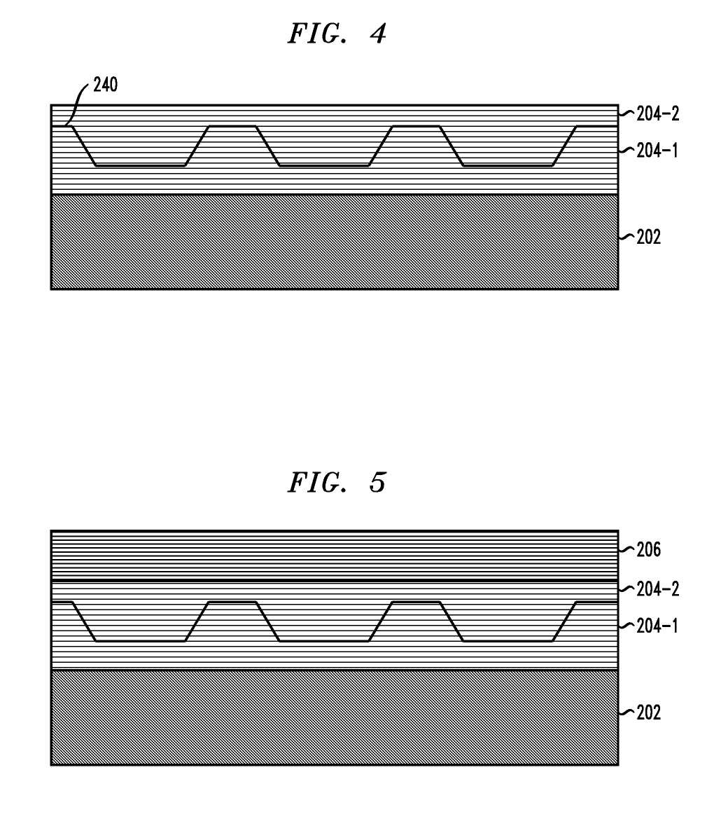

After forming the patterned buried layer 204-1, the tops of the mesas may be patterned with photo-resist. As shown in FIG. 4, a patterned buried layer 204-2 is then selectively re-grown over the patterned buried layer 204-1. The patterned buried layer 204-2 may be a DBR which matches the patterned buried layer 204-1. For example, the patterned buried layer 204-1 and 204-2 may both be formed of alternating layers of n-doped InGaN and GaN. FIG. 4 shows an embodiment where the patterned buried layer 204-2 is grown so as to fill in and exceed the mesa hollows of patterned buried layer 204-1 so as to smooth the morphology. In other embodiments, the patterned buried layer 204-2 may be grown so as to only fill in the mesa hollows of patterned buried layer 204-1 or may not entirely fill in the mesa hollows of patterned buried layer 204-1. The patterned buried layers 204-1 and 204-2, combined, may vary in thickness as desired. In some embodiments, the patterned buried layers 204-1 and 204-2, combined, have a thickness in the range of 20 to 100 nm.

A slight discontinuity 240, represented by the bold line between patterned buried layers 204-1 and 204-2 in FIG. 4, is formed between the mesas of the patterned buried layer 204-1 and the selective re-grow of patterned buried layer 204-2. This discontinuity 240 provides a patterned structure which is hidden within the buried layer structure. The discontinuity enhances the light extraction efficiency of the LED structure.

Next, an active layer 206 is formed over the patterned buried layer 204-2. The resulting structure is shown in FIG. 5. In some embodiments, the active layer is formed of alternating layers of InGaN and GaN. The active layer may be formed with any desired thickness. In some embodiments, the active layer 206 has a thickness in the range of 20 to 60 nm.

After forming the active layer 206, a second buried layer 208 is formed over the active layer 206. The second buried layer 208 may be a DBR formed of alternating layers of InGaN and GaN as described above. In embodiments where the patterned buried layers 204-1 and 204-2 are n-doped, the second buried layer 208 may be p-doped. In other embodiments, the second buried layer 208 may be p-doped and the patterned buried layers 204-1 and 204-2 may be n-doped.

A similar process as that described above with respect to FIGS. 3 and 4 is performed for the second buried layer 208. A portion of the second buried layer 208 is removed to create a second patterned buried layer 208-1 with one or more raised mesa structures as shown in FIG. 7. ICP-RIE may be used to create the one or more raised mesa structures in the second patterned buried layer 208-1.

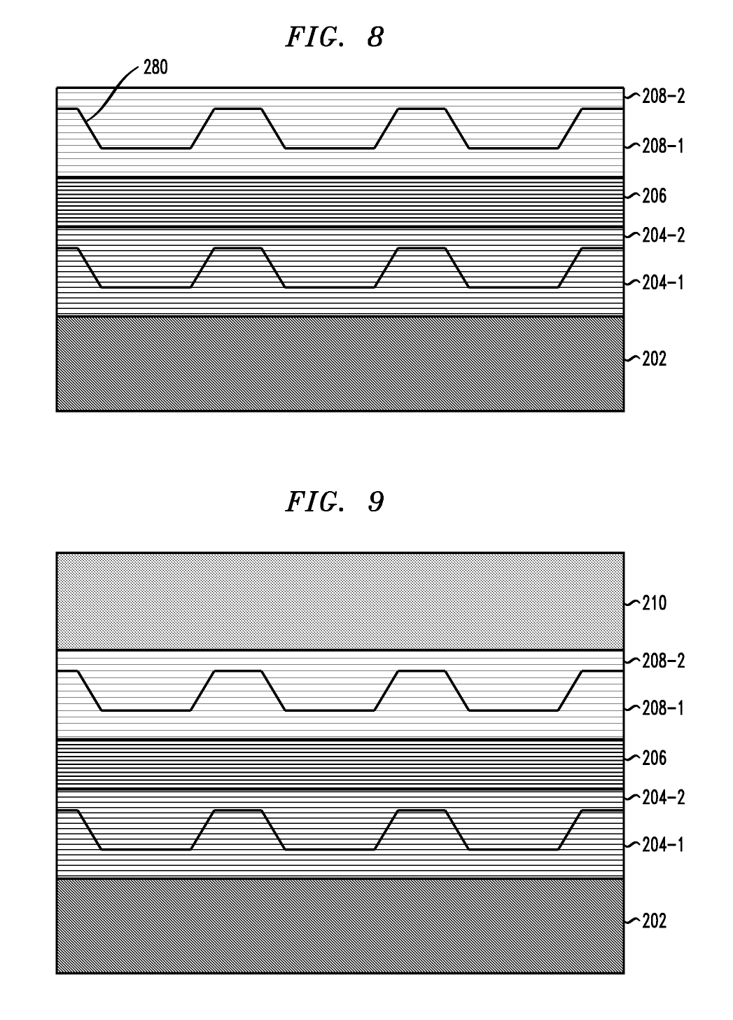

After forming the second patterned buried layer 208-1, the tops of the mesas may be patterned with photo-resist as described above. As shown in FIG. 8, a second patterned buried layer 208-2 is then selectively re-grown over the second patterned buried layer 208-1. The second patterned buried layer 208-2 may be a DBR which matches the second patterned buried layer 208-1. For example, both the second patterned buried layer 208-1 and 208-2 may be formed of alternating layers of p-doped InGaN and GaN. As described above with respect to patterned buried layer 204-2, the second patterned buried layer 208-2 may completely fill and exceed the mesa hollows of second patterned buried layer 208-1 so as to smooth the morphology. The second patterned buried layer 208-2 may also be formed such that it completely fills but does not exceed the mesa hollows of second patterned buried layer 208-1 or may not completely fill the mesa hollows of second patterned buried layer 208-2. The patterned buried layers 208-1 and 208-2, combined, may vary in thickness as desired. In some embodiment, the patterned buried layers 208-1 and 208-2, combined, have a thickness in the range of 20 to 100 nm.

Again, as described above with respect to patterned buried layers 204-1 and 204-2, a discontinuity 280 is formed between the mesas of the second patterned buried layer 208-1 and the second patterned buried layer 208-2 which enhances the light extraction efficiency of the LED structure. Finally, a capping layer 210 is formed over the second patterned buried layer 208-2. In some embodiments, the capping layer is GaN. The capping layer 210 may vary in thickness as desired. In some embodiments, the capping layer 210 has a thickness of 60 to 100 nm.

Each of the buried layer 204, the patterned buried layer 204-2, the second buried layer 208, and the second patterned buried layer 208-2 may be grown using MOCVD as described above. The raised mesa structures in the patterned buried layer 204-1 and the patterned buried layer 208-1 may be formed using ICP-RIE as described above. In other embodiments, the raised mesa structures may be formed using dry or wet etching. One skilled in the art will readily appreciate that various other processes may be used to form the substrate 202, the patterned buried layers 204-1 and 204-2, the active layer 206, the second patterned buried layers 208-1 and 208-2 and the capping layer 210.

It is important to note that while various steps and processes for forming the LED structure of FIG. 9 have been described in FIGS. 2-9 in a particular order, embodiments of the invention are not limited to this particular order. Instead, various steps and processes as described above may be performed in a different order or may not be performed at all. In addition, various steps and processes which are described above as occurring in a sequential manner may be performed substantially simultaneously. The LED structure of FIG. 9 may be formed such that the LED may be used with a 5 mm packaging scheme. Embodiments of the invention, however, are not limited to use solely with 5 mm packaging schemes but instead are more broadly applicable to various other packaging schemes as will be appreciated by one skilled in the art.

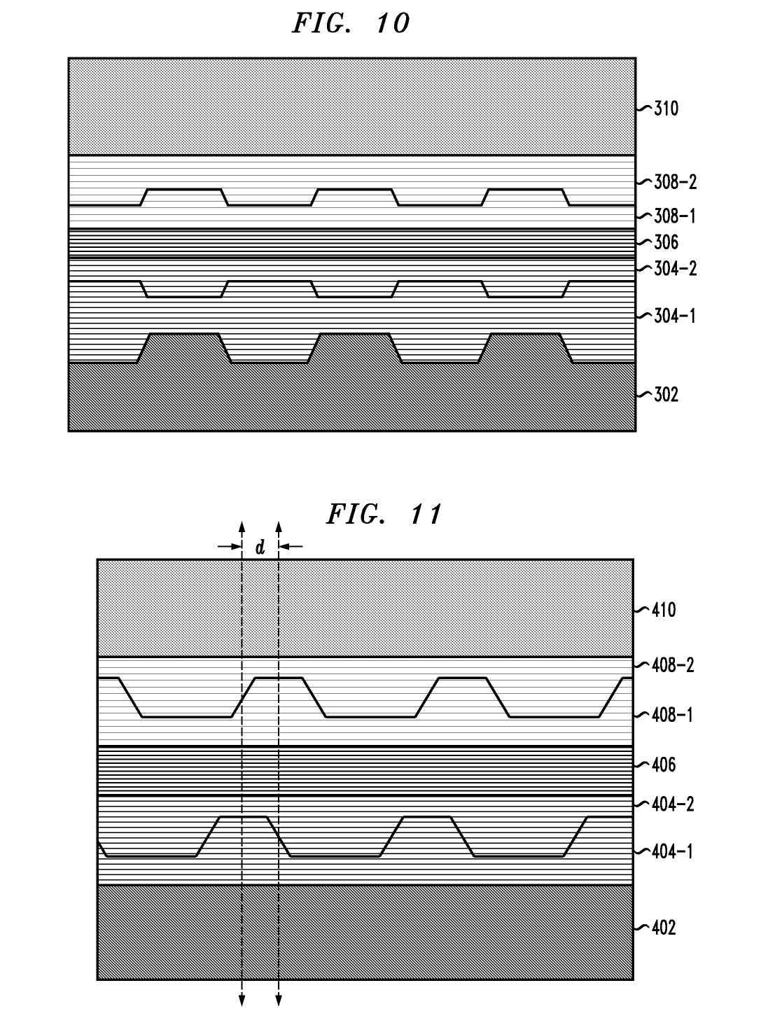

FIG. 10 shows an alternate LED structure with a patterned substrate 302. The LED structure of FIG. 10 has patterned buried layers 304-1 and 304-2, active layer 306, second patterned buried layers 308-1 and 308-2 and capping layer 310, which correspond to patterned buried layers 204-1 and 204-2, active layer 206, second patterned buried layers 208-1 and 208-2 and capping layer 210 as shown in the LED structure of FIG. 9. The patterned substrate 302 can further enhance light extraction efficiency of the LED structure. The mesa structures of the patterned substrate 302 may be formed using ICP-RIE as described above.

FIG. 11 shows an alternate LED structure with a substrate 402, patterned buried layers 404-1 and 404-2, active layer 406, second patterned buried layers 408-1 and 408-2 and capping layer 410 which correspond to patterned buried layers 204-1 and 204-2, active layer 206, second patterned buried layers 208-1 and 208-2 and capping layer 210 as shown in the LED structure of FIG. 9. As shown in FIG. 11, however, the mesa structures of the patterned buried layer 404-1 are offset by a distance d from the mesa structures of second patterned buried layer 408-1. This offset produces a cupping effect, which further enhances the light extraction efficiency of the LED structure.

It should be emphasized that the above-described embodiments of the invention are intended to be illustrative only. For example, while the LED structures in FIGS. 9-11 show two sets of patterned buried layers (204 and 208, 304 and 308, 404 and 408), embodiments of the invention are not limited solely to this arrangement. In some embodiments, only a single set of patterned buried layers may be formed on one side of the active layers 206, 306, 308. In other embodiments, additional sets of patterned buried layers may be formed.

As another example, the heights of the mesa structures in the sets of patterned buried layers may vary. For instance, in the structure of FIG. 9, the height of the mesa structures in patterned buried layer 204-1 may be greater than the height of the mesa structures in second patterned buried layer 208-1. In addition, although the mesa structures in FIGS. 9-11 are shown with a uniform height within a given layer, embodiments include LED structures where the height of the mesa structures can vary within the same layer. For instance, in the structure of FIG. 9, a first mesa structure in patterned buried layer 204-1 may have a first height while a second mesa structure in patterned buried layer 204-1 may have a second height different than the first. The heights of the mesa structures within a layer may alternate with every mesa structure (i.e., first mesa structure is height A, second mesa structure is height B, third mesa structure is height A) or may alternate with every two or three or any number of mesa structures. Non-alternating patterns may also be used. These and numerous other alternative embodiments within the scope of the following claims will be apparent to those skilled in the art.

What is claimed is:

1. An apparatus, comprising:
a substrate;
a first buried layer formed over the substrate, the first buried layer comprising one or more raised mesa structures;
a second buried layer formed over the first buried layer;
an active layer formed over the second buried layer; and
a capping layer formed over the active layer.

2. The apparatus of claim 1, wherein the second buried layer is formed such that one or more hollows of the one or more raised mesa structures of the first buried layer are filled.

3. The apparatus of claim 1, wherein at least one of the first buried layer and the second buried layer comprises a distributed Bragg reflector (DBR).

4. The apparatus of claim 1, wherein at least one of the first buried layer and the second buried layer comprises alternating layers of Indium Gallium Nitride (InGaN) and Gallium Nitride (GaN).

5. The apparatus of claim 1, wherein the at least one raised mesa structure is formed using inductively coupled-plasma reactive-ion etching (ICP-RIE).

6. The apparatus of claim 1, further comprising:
a third buried layer formed over the active layer, the third buried layer comprising one or more raised mesa structures; and
a fourth buried layer formed over the third buried layer.

7. The apparatus of claim 6, wherein the first buried layer and the second buried layer are doped with a first conductivity type and the third buried layer and the fourth buried layer are doped with a second conductivity type different than the first conductivity type.

8. The apparatus of claim 6, wherein the one or more raised mesa structures of the first buried layer are offset from the one or more raised mesa structures of the third buried structure layer.

9. The apparatus of claim 1, wherein the substrate comprises:
a first substrate layer; and
a second substrate layer over the first substrate layer.

10. The apparatus of claim 9, wherein the first substrate layer comprises sapphire and the second substrate layer comprises Gallium Nitride (GaN).

11. The apparatus of claim 9, wherein the first substrate layer comprises at least one raised mesa structure.

12. The apparatus of claim 1, wherein the active layer comprises Indium Gallium Nitride (InGaN).

13. The apparatus of claim 1, wherein the capping layer comprises Gallium Nitride (GaN).

14. A method comprising:
forming a substrate;
forming a first buried layer over the substrate;
removing a portion of the first buried layer to create one or more raised mesa structures in the first buried layer;
forming a second buried layer over the first buried layer;
forming an active layer over the second buried layer; and
forming a capping layer over the active layer.

15. The method of claim 14, wherein the step of forming a capping layer comprises:
forming a third buried layer over the active layer;
removing a portion of the third buried layer to create one or more raised mesa structures in the third buried layer;
forming a fourth buried layer over the third buried layer; and
forming the capping layer over the fourth buried layer.

16. The method of claim 15, wherein the one or more raised mesa structures of the first buried layer are offset from the one or more raised mesa structures of the third buried structure layer.

17. A device, comprising:
one or more light-emitting diodes (LEDs); and
control circuitry configured to control at least one of the one or more LEDs;
wherein at least one of the one or more LEDs comprises: a substrate; a first buried layer formed over the substrate, the first buried layer comprising one or more raised mesa structures; a second buried layer formed over the first buried layer; an active layer formed over the second buried layer; and a capping layer formed over the active layer.

18. The device of claim 17, wherein the at least one LED further comprises:
a third buried layer formed over the active layer, the third buried layer comprising one or more raised mesa structures; and
a fourth buried layer formed over the third buried layer.

19. The device of claim 18, wherein the one or more raised mesa structures of the first buried layer are offset from the one or more raised mesa structures of the third buried layer.

20. The device of claim 17, further comprising a display.

21. A lighting fixture comprising the device of claim 17.
